(19) United States
(12) Patent Application Publication
(10) Pub. No.: US 2025/0118534 A1
(43) Pub. Date: Apr. 10, 2025

(54) SYSTEMS AND METHODS FOR CENTRAL FREQUENCY TUNING

(71) Applicant: Lam Research Corporation, Fremont, CA (US)

(72) Inventors: Ranadeep Bhowmick, San Jose, CA (US); John P. Holland, San Jose, CA (US)

(21) Appl. No.: 18/836,329

(22) PCT Filed: Dec. 21, 2022
(86) PCT No.: PCT/US22/53727

§ 371 Date: Aug. 6, 2024

Related U.S. Application Data
(60) Provisional application No. 63/311,920, filed on Feb. 18, 2022.

(51) Int. Cl. H01J 37/32

(52) U.S. Cl. CPC H01J 37/32183; H01J 37/32165; H01J 37/32926; H01J 37/32935; H01J 37/3299

(57) ABSTRACT

Systems and methods for central frequency tuning are described. One of the methods includes receiving a voltage signal from an output of a match coupled to a low frequency (LF) radio frequency (RF) generator and a high frequency (HF) RF generator. The method further includes dividing the voltage signal into a plurality of bins for each cycle of an LF RF signal generated by the LF RF generator. The method also includes identifying a first bin from the plurality of bins during which a zero crossing occurs, accessing measurements of a parameter for occurrences of a pre-determined number of the plurality of bins, and calculating a frequency of operation of the HF RF generator for the first bin based on the measurements of the parameter. The method includes controlling the HF RF generator to operate at the frequency of operation during an occurrence of the first bin.

### FIELD

The embodiments described in the present disclosure relate to systems and methods for central frequency tuning.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

One or more radio frequency (RF) generators are coupled to a plasma chamber. Within the plasma chamber, a semiconductor wafer is placed. The one or more RF generators supply one or more RF signals to the plasma chamber to process the semiconductor wafer. It is desirable that the semiconductor wafer be processed in an accurate manner. Otherwise, efficiency in processing the semiconductor wafer reduces.

It is in this context that embodiments described in the present disclosure arise.

### SUMMARY

Embodiments of the disclosure provide systems and methods for central frequency tuning. It should be appreciated that the present embodiments can be implemented in numerous ways, e.g., a process, an apparatus, a system, a piece of hardware, or a method on a computer-readable medium. Several embodiments are described below.

In an embodiment, a method for reducing radio frequency (RF) power reflected towards a high frequency (HF) RF generator in a bin independent manner is described. The method includes receiving a voltage signal from an output of a match coupled to a low frequency (LF) RF generator an HF RF generator. The method further includes dividing the voltage signal into a plurality of bins for each cycle of an LF RF signal generated by the LF RF generator. The method also includes identifying a first bin from the plurality of bins during which a zero crossing occurs, accessing measurements of a parameter for occurrences of a pre-determined number of the plurality of bins, and calculating a frequency of operation of the HF RF generator for the first bin based on the measurements of the parameter. The method includes controlling the HF RF generator to operate at the frequency of operation during an occurrence of the first bin.

In one embodiment, a controller for reducing RF power reflected towards an HF RF generator in a bin independent manner is described. The controller includes a processor. The processor receives a voltage signal from an output of a match coupled to an LF RF generator and the HF RF generator. The processor further divides the voltage signal into a plurality of bins for each cycle of an LF RF signal generated by the LF RF generator, identifies a first bin from the plurality of bins during which a zero crossing occurs, and accesses measurements of a parameter for occurrences of a pre-determined number of the plurality of bins. The processor calculates a frequency of operation of the HF RF generator for the first bin based on the measurements of the parameter and controls the HF RF generator to operate at the frequency of operation during an occurrence of the first bin. The controller includes a memory device coupled to the processor.

In an embodiment, a plasma system is described. The plasma system includes an LF RF generator that generates an LF RF signal. The plasma system further includes an HF RF generator that generates an HF RF signal. The plasma system includes a match coupled to the LF RF generator and the HF RF generator. The match receives the LF RF and HF RF signals to output a modified RF signal. The plasma system also includes a controller coupled to the LF RF generator, the HF RF generator, and the match. The controller receives a voltage signal from an output of the match, divides the voltage signal into a plurality of bins for each cycle of the LF RF signal, and identifies identify a first bin from the plurality of bins during which a zero crossing occurs. The controller further accesses measurements of a parameter for occurrences of a pre-determined number of the plurality of bins and calculates a frequency of operation of the HF RF generator for the first bin based on the measurements of the parameter. The processor controls the HF RF generator to operate at the frequency of operation during an occurrence of the first bin.

Some advantages of the herein described systems and methods for central frequency tuning include accounting for a parameter for a pre-determined number of bins or all bins during a cycle of operation of an LF RF generator. By considering the pre-determined number of bins or all bins during the cycle of operation of the LF RF generator, reflected HF RF power is reduced in a more accurate manner across the entire cycle of operation of the LF RF generator compared to when a parameter for a single bin is considered. The parameter is determined for the pre-determined number of bins or all bins of the cycle of operation of the LF RF generator. From the values of the parameter for the pre-determined number of bins or all bins, a statistical value of the parameter is determined. Based on the statistical value, a reference high frequency value is determined for a bin 0. HF offset values are then determined from the reference high frequency value for remaining ones of the pre-determined number of bins during the cycle of operation of the LF RF generator.

The reflected power is reduced in a bin independent manner when the pre-determined number of bins or all the bins during the cycle of operation of the LF RF generator are considered. For example, in addition to considering the reflected HF power for the bin 0, the reflected HF power is considered for additional bins during the cycle of operation of the LF RF generator. As such, the reflected HF RF power is reduced independent of the bin 0.

Further advantages of the herein described systems and methods for central frequency tuning include using a statistical value, such as an average, of reflected power for the pre-determined number of bins or all bins during a cycle of operation of an LF RF signal to determine a central frequency. Sometimes, it is difficult to identify the bin 0 and to reduce reflected power based only on bin 0. When the bin 0 is incorrectly identified, it leads to mistunes. By using the statistical value, chances of mistunes rising from bin mis-identification are substantially reduced.

Some other aspects will become apparent from the following detailed description, taken in conjunction with the accompanying drawings.

### BRIEF DESCRIPTION OF THE DRAWINGS

The embodiments are understood by reference to the following description taken in conjunction with the accompanying drawings.

FIG. 1 is a diagram of an embodiment of a plasma system to illustrate use of a low frequency (LF) radio frequency (RF) generator and a high frequency (HF) RF generator.

FIG. 2A is an embodiment of a graph to illustrate a clock signal.

FIG. 2B is a diagram of an embodiment of a graph that plots a voltage signal, such as a delivered voltage signal, to illustrate binning.

FIG. 2C is an embodiment of a graph to illustrate a method for determining a reference high frequency value for a bin 0 based on multiple values of a parameter for bins 1 through 10 during a cycle of a clock signal.

FIG. 3A is an embodiment of a graph to illustrate a clock signal.

FIG. 3B is an embodiment of a graph to illustrate an RF signal that is generated by the LF RF generator.

FIG. 3C is an embodiment of a graph to illustrate that values of the parameter during a hold-off period and during a frequency tuning period are used to determine the reference high frequency value.

### DETAILED DESCRIPTION

The following embodiments describe systems and methods for central frequency tuning. It will be apparent that the present embodiments may be practiced without some or all of these specific details. In other instances, well known process operations have not been described in detail in order not to unnecessarily obscure the present embodiments.

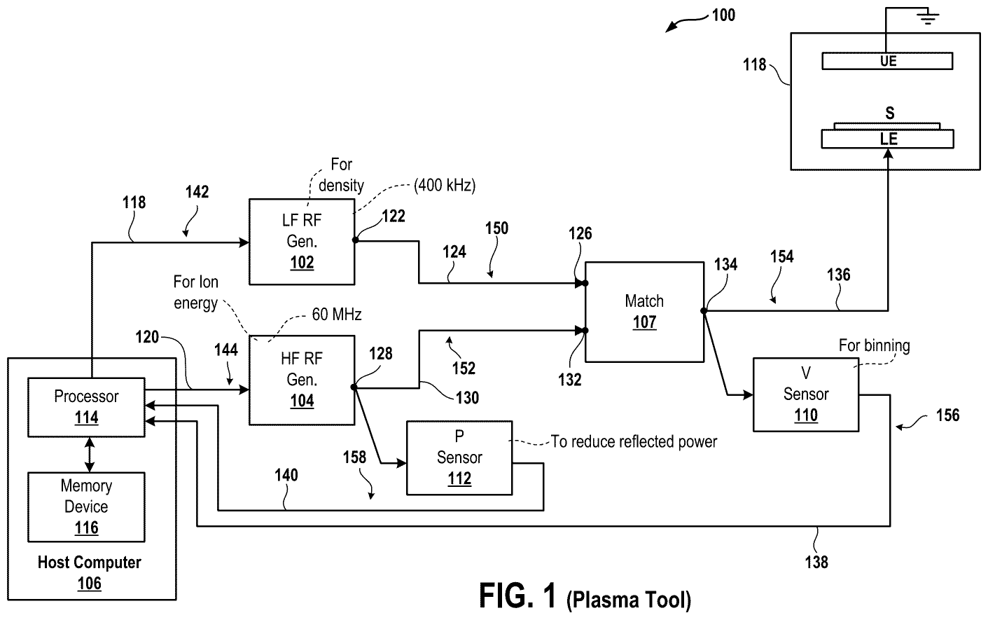

FIG. 1 is a diagram of an embodiment of a plasma system 100 to illustrate use of a low frequency (LF) RF generator 102 and a high frequency (HF) RF generator 104. The system 100 includes the LF RF generator 102, the HF RF generator 104, a host computer 106, a match 107, and a plasma chamber 108. The plasma system 100 further includes a voltage (V) sensor 110 and a power (P) sensor 112.

As an example, the LF RF generator 102 has a frequency of operation of 400 kilohertz (kHz), or 2 megahertz (MHz). Also, as an example, the HF RF generator 104 has a frequency of operation of 27 MHz or 60 MHz. Examples of the host computer 106 includes a desktop, a laptop, a tablet, a controller, and a smart phone. An example of a controller, as described herein, is a combination of a processor and a memory device. The processor of the controller is coupled to the memory device of the controller. An example of the match 107 is an impedance matching circuit or an impedance match or a match circuit or an impedance matching network. To illustrate, the match 107 includes a first branch circuit and a second branch circuit. Each branch circuit includes one or more match network elements. Examples of match network elements include capacitors, inductors, and resistors. An example of the plasma chamber 108 is a capacitively coupled plasma (CCP) chamber.

The host computer 106 includes a processor 114 and a memory device 116. Examples of the processor 114 include a central processing unit (CPU), an application specific integrated circuit (ASIC), and a programmable logic device (PLD). Examples of the memory device 116 include a read-only memory and a random access memory.

The plasma chamber 108 includes a lower electrode LE and an upper electrode UE. A gap is formed between the lower electrode LE and the upper electrode UE and a substrate S is placed within the gap on a top surface of the lower electrode LE for processing. An example of the substrate S includes a semiconductor wafer on which an integrated circuit is fabricated.

The processor 114 is coupled to the memory device 116. The processor 114 is coupled via a transfer cable 118 to the LF RF generator 102 and via a transfer cable 120 to the HF RF generator 104. An example of a transfer cable includes an electric cable that transfers data in a parallel manner or in a serial manner or using a universal serial bus (USB) protocol. The LF RF generator 102 has an output 122 that is coupled via an RF cable 124 to an input 126 of the match 107. Similarly, the HF RF generator 104 has an output 128 that is coupled via an RF cable 130 to an input 132 of the match 107. The match 107 has an output 134, which is coupled via an RF transmission line 136 to the lower electrode LE. The first branch circuit of the match 107 is coupled between the input 126 and the output 134, and the second branch circuit of the match 107 is coupled between the input 132 and the output 134. The upper electrode UE is coupled to a ground potential.

The V sensor 110 is coupled via a transfer cable 138 to the processor 114 and the P sensor 112 is coupled via a transfer cable 140 to the processor 114. The V sensor 110 is coupled to the output 134 of the match 134. Also, the P sensor 112 is coupled to the output 128 of the HF RF generator 104.

The processor 114 generates a recipe signal 142, which includes a low frequency and one or more power levels of an RF signal 150 to be generated by the LF RF generator 102. As an example, the low frequency is equal to the frequency of operation of the LF RF generator 102. The processor 114 sends the recipe signal 142 via the transfer cable 118 to the LF RF generator 102. Also, the processor 114 generates a recipe signal 144, which includes a high frequency and one or more power levels of an RF signal 152 to be generated by the HF RF generator 104. As an example, the high frequency is equal to the frequency of operation of the HF RF generator 104. The processor 114 sends the recipe signal 144 via the transfer cable 120 to the HF RF generator 104.

Upon receiving the recipe signal 142, the LF RF generator 102 generates the RF signal 150 having the low frequency and the one or more power levels indicated within the recipe signal 142. The LF RF generator 102 sends the RF signal 150 via the output 122, the RF cable 124, and the input 126 to the match 107. Similarly, upon receiving the recipe signal 144, the HF RF generator 104 generates the RF signal 152 having the high frequency and the one or more power levels indicated within the recipe signal 144. The HF RF generator 104 sends the RF signal 152 via the output 128, the RF cable 130, and the input 132 to the match 107.

Upon receiving the RF signal 150, the first branch circuit of the match 107 matches an impedance of a load coupled to the output 134 with an impedance of a source coupled to the input 126 to modify an impedance of the RF signal 150 to provide a first modified RF signal. An example of the load coupled to the output 134 includes the RF transmission line 136 and the plasma chamber 108. An example of the source coupled to the input 126 includes the RF cable 124 and the LF RF generator 102. Similarly, upon receiving the RF signal 152, the second branch circuit of the match 107 matches an impedance of the load coupled to the output 134 of the match 107 with an impedance of a source coupled to the input 132 of the match 107 to modify an impedance of the RF signal 152 to provide a second modified RF signal.

The match 107 combines, such as adds, the first and second modified RF signals to output a modified RF signal 154 at the output 134. The modified RF signal 154 is sent from the output 134 via the RF transmission line 136 to the lower electrode LE. When one or more process gases, such as a fluorine containing gas, an oxygen containing gas, a nitrogen containing gas, etc., are supplied to the gap between the lower electrode LE and the upper electrode UE, in addition to the modified RF signal 154, plasma is stricken or maintained within the gap. The plasma processes the substrate S. Examples of processing the substrate S include etching features within the substrate S, depositing materials on the substrate S, and cleaning the substrate S.

While the substrate S is being processed, the V sensor 110 measures a voltage at the output 134 to output a voltage signal 156 and sends the voltage signal 156 via the transfer cable 138 to the processor 114. Similarly, while the substrate S is being processed, the P sensor 112 measures power, such as high frequency delivered power or high frequency reflected power, at the output 134 to output a power signal 158 and sends the power signal 158 via the transfer cable 140 to the processor 114. As an example, power is reflected towards the HF RF generator 104 from the plasma chamber 108, the RF transmission line 136, the match 107, and the RF cable 130. The power reflected towards the HF RF generator 104 is sometimes referred to herein as the high frequency reflected power.

In an embodiment, the V sensor 110 is coupled at any point on the RF transmission line 136.

In one embodiment, the P sensor 112 is coupled at any point on the RF cable 130.

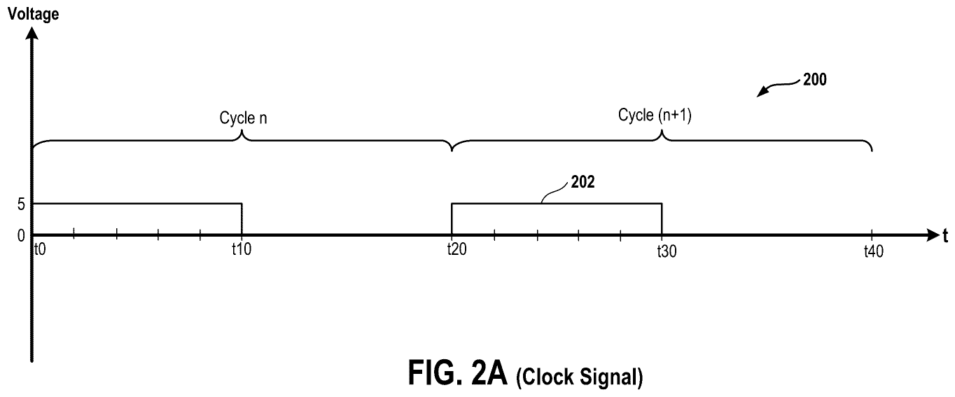

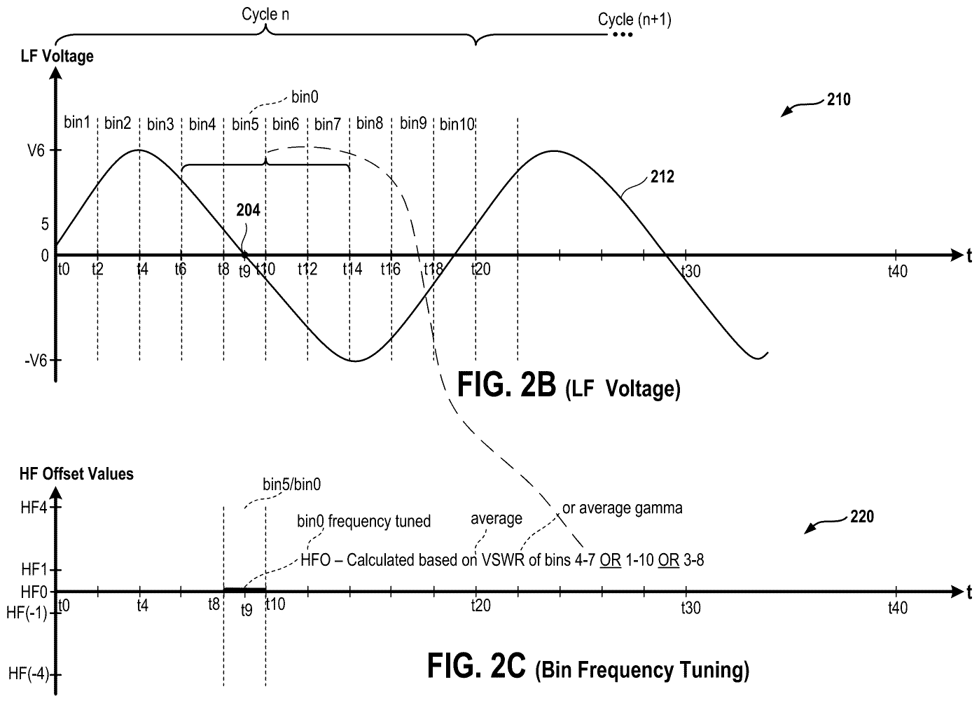

FIG. 2A is an embodiment of a graph 200 to illustrate a clock signal 202. As an example, the clock signal 202 is generated by the processor 114 (FIG. 1). An x-axis of the graph 200 plots time t ranging from a time t0 to a time t40. A y-axis of the graph 200 plots a voltage of the clock signal 202. The clock signal 202 transitions periodically between a logic level 1 and a logic level 0. The logic level 1 corresponds to 5 volts and the logic level 0 corresponds to zero volts.

The clock signal 202 transitions from the logic level 0 to the logic level 1 at the time t0 and remains at the logic level 1 from the time t0 to the time t10. At the time t10, the clock signal 202 transitions from the logic level 1 to the logic level 0, and remains at the logic level 0 from the time t10 to the time t20. The transitions between the logic levels 1 and 0 repeat from the time t20 to the time t40. The clock signal 202 has a cycle n from the time t0 to the time t20 and a consecutively following cycle (n+1) from the time t20 to the time t40, where n is a positive integer

FIG. 2B is a diagram of an embodiment of a graph 210 that plots a voltage signal 212, such as a delivered voltage signal, to illustrate binning. As an example, the graph 210 is generated by the processor 114 (FIG. 1) upon receiving the voltage signal 212 from the V sensor 110 (FIG. 1).

The graph 210 plots the voltage signal 220 versus the time t. For example, a y-axis of the graph 210 represents a voltage of the voltage signal 220 and an x-axis of the graph 210 represents the time t. The y-axis plots multiple voltage values, starting in a positive y-direction from V0 to V6. Also, the y-axis plots multiple voltage values, starting in a negative y-direction from V0 to −V6. The voltage value V6 is greater than the voltage value V0 and the voltage value −V6 is less than the voltage value V0. To illustrate, the voltage value V0 is zero. As another illustration, the voltage value V0 is negative. As an example, the x-axis of the graph 210 represents the time t at which the voltage values of the voltage signal 212 are received by the processor 114 from the V sensor 110.

The voltage signal 212 is an example of the voltage signal 156 (FIG. 1) generated by the V sensor 110 (FIG. 1). The voltage signal 212 represents a voltage of the first modified RF signal or primarily represents a voltage of the RF signal 150 generated by the LF RF generator 102. For example, the voltage signal 212 represents the voltage of the RF signal 150. As another example, the voltage signal 212 primarily represents the voltage of the RF signal 150 and minimally represents a voltage of the RF signal 152. To illustrate, a voltage of the voltage signal 212 is a voltage of the RF signal 150. As another illustration, 90% of a voltage of the voltage signal 212 is a voltage of the RF signal 150 and the remaining 10% of the voltage of the voltage signal 212 is a voltage of the RF signal 152. The voltage signal 212 extends over multiple clock cycles of the clock signal 202 (FIG. 2A). For example, the voltage signal 212 extends from the time t0 to the time t20, and a time interval between the times t0 to t20 represents the cycle n of the clock signal 202. The voltage signal 212 further extends from the time t20 to the time t40, and a time interval between the times t20 to t40 represents the cycle (n+1) of the clock signal 202.

The processor 114 divides the voltage signal 212 during each cycle of the clock signal 202 into multiple bins, such as 10 or 20 bins. For example, during the cycle n, the voltage signal 212 is divided into bins 1 through 10 and during the cycle (n+1), the voltage signal 212 is divided into bins 1 through 10, and so on. To further illustrate, the processor 114 divides the voltage signal 212 during each cycle of the clock signal 202. The voltage signal 212 is divided into ten equal time intervals during each cycle, and each time interval is designated by the processor 114 as a bin.

The processor 114 extends each bin across the same time interval. For example, the bin 1 extends from the time t0 to the time t2, the bin 2 extends from the time t2 to the time t4, the bin 3 extends from the time t4 to the time t6, the bin 4 extends from the time t6 to the time t8, and the bin 5 extends from the time t8 to the time t10. The bin 5 is sometimes referred to herein as a bin 0. Also, the bin 6 extends from the time t10 to the time t12, the bin 7 extends from the time t12 to the time t14, the bin 8 extends from the time t14 to the time t16, the bin 9 extends from the time t16 to the time t18, and the bin 10 extends from the time t18 to the time t20

The processor 114 identifies the bin 0 as a time interval that includes a point at which the voltage signal 212 intersects the x-axis and determines the point to be a negative zero crossing 214. For example, the processor 114 determines the point at which a voltage of the voltage signal 212 is zero and a slope of the voltage signal 212 is negative to be the negative zero crossing 214. As another example, at the negative zero crossing 214, a voltage of the voltage signal 212 is non-zero. The slope of the voltage signal 212 is negative during the time interval of the bin 0. The processor 114 identifies, such as designates, one of the bins 1 through 10 that include the negative zero crossing 214 to be the bin 0.

The bins 1 through 4 and a first portion of the bin 0 form a positive cycle of the voltage signal 212 and a second portion of the bin 0 and the bins 6 through 10 form a negative cycle of the voltage signal 212. The first portion of the bin 0 that is a part of the positive cycle of the voltage signal 212 extends for a time interval from the time t8 to a time t9 at which the negative crossing 214 occurs. Also, the second portion of the bin 0 that is a part of the negative cycle of the voltage signal 212 extends for a time interval from the time t9 to the time t10.

FIG. 2C is an embodiment of a graph 220 to illustrate a method for determining a reference high frequency value HF0 for the bin 0 based on multiple values of a parameter for the bins 1 through 10 during a cycle (n−m) of the clock signal 202, where m is an integer less than the integer n. An example of the cycle (n−m) is the cycle (n−1) or the cycle (n−2). Examples of the parameter include a voltage standing wave ratio (VSWR) and a reflection coefficient (T).

The graph 220 plots HF offset values of the RF signal 152 (FIG. 1) versus the time t. As an example, the HF offset values plotted on the graph 220 are examples of a frequency of operation of the HF RF generator 104 (FIG. 1). The HF offset values of the RF signal 152 are plotted on a y-axis and the time t is plotted on an x-axis, which is the same as the x-axis of the graph 200 (FIG. 2A). As an example, the HF offset values plotted on the y-axis of the graph 220 range from HF(−4) to HF4. The HF offset value HF4 is greater than the HF offset value HF0 and the HF offset value HF(−4) is less than the reference high frequency value HF0.

The processor 114 determines, such as identifies or establishes, the reference high frequency value HF0 based on the values of the parameter for all the bins 1 through 10 during the cycle (n−m). For example, the processor 114 controls the HF RF generator 104 to operate at the reference high frequency value HF0 during the bin 0 of the cycle (n−m). The processor 114 calculates a first set of ten values of the parameter for the bins 1 through 10 during the cycle (n−m) when the HF RF generator 104 operates based on the reference high frequency value HF0. As an illustration, the processor 114 controls the HF RF generator 104 to operate at the HF offset value HF(−4) during the bin 1 of the cycle (n−m). The HF offset value HF(−4) is an offset of frequency from the reference high frequency value HF0. For instance, the HF offset value HF(−4) is less than the reference high frequency value HF0 by 4 MHz.

The processor 114 accesses a correspondence, such as a one-to-one relationship, between the HF offset value HF(−4) and the bin 1 from the memory device 116 (FIG. 1) to determine that the HF offset value HF(−4) is to be applied during the bin 1 of the cycle (n−m). The HF offset value HF(−4) is an offset, such as a subtraction, from the reference high frequency value HF0. Also, it should be noted that the HF offset values of the HF RF generator 104 are controlled to have a substantially inverse relationship or an inverse relationship with the voltage signal 212 during the cycle (n−m). During a time period in which the voltage signal 212 forms the positive cycle, the HF offset values of the HF RF generator 104 are controlled to be negative offsets from the reference high frequency value HF0 and during a time period in which the voltage signal 212 forms the negative cycle, the HF offset values of the HF RF generator 104 are controlled to be positive offsets from the reference high frequency value HF0.

Continuing with the illustration, when the HF RF generator 104 is operated at the HF offset value HF(−4) during the bin 1, the processor 114 receives the voltage signal 212 during the bin 1 from the V sensor 110 (FIG. 1) and calculates a first value of the parameter for the bin 1 of the cycle (n−m) by determining a ratio of a reflected voltage Vᵣ to a forward voltage V_{f}. The ratio of the reflected voltage Vᵣ during the bin 1 to the forward voltage V_{f} during the bin 1 is the reflection coefficient during the bin 1. The reflected voltage Vᵣ is reflected from the plasma chamber 108 (FIG. 1) via the RF transmission line 136, the second branch circuit of the match 107, and the RF cable 130 towards the HF RF generator 104. The forward voltage V_{f} is voltage of the RF signal 152 supplied from the RF generator 104 via the RF cable 130, the match 107, and the RF transmission line 136 to the lower electrode LE. The forward voltage V_{f} during the bin 1 is stored in the memory device 116 for access by the processor 144. The processor 114 determines the reflected voltage Vᵣ as a difference between a delivered voltage during the bin 1 of the voltage signal 212 and the forward voltage V_{f} during the bin 1. The processor 114 determines the delivered voltage to be a statistical value, such as an average or a median, of voltage values of the voltage signal 212 received during the bin 1. The statistical value is the first value of the parameter for the bin 1. In a similar manner to that of determining the first value of the parameter for the bin 1, the processor 114 determines the remaining nine parameter values of the first set for the bins 2 through 10 of the cycle (n−m). During each of the bins 2 through 10 of the cycle (n−m), the processor 114 controls the HF RF generator 104 to operate at nine HF offset values, such as different HF offset values, and each of the nine HF offset values is associated with, e.g., has a one-to-one correspondence with, a corresponding one of the bins 2 through 10 of the cycle (n−m). It should be noted that during the bin 0 of the cycle (n−m), the HF offset value is zero. During the bin 0, the processor 114 controls the HF RF generator 104 to operate at the reference high frequency value HF0.

Continuing further with the illustration, the processor 114 accesses the correspondence from the memory device 116 to operate the HF RF generator 104 at the nine HF offset values. When the HF RF generator 104 operates at the nine HF offset values, the processor 114 receives values of the voltage signal 212 from the V sensor 110 during the bins 2 through 10 of the cycle (n−m), and calculates nine values of the parameter in the same manner in which the first value is calculated for the bin 1. The nine values of the parameter form a part of the first set of parameter values. The processor 114 then calculates a statistical value, such as an average or a median, of the first set of values of the parameter to output a first statistical parameter value.

Continuing with the example, the processor 114 controls the HF RF generator 104 to operate at a reference high frequency value HF0′ during the bin 0 of a cycle (n−m+p), where p is a positive integer, and (n−m+p) is an integer that is greater than (n−m) and less than n. The processor 114 calculates a second set of ten values of the parameter for the bins 1 through 10 during the cycle (n−m+p) when the HF RF generator 104 operates at the reference high frequency value HF0′ in the same manner in which the processor 114 calculates the first set of ten values of the parameter. To illustrate, the processor 114 applies the offsets, both positive and negative, from the reference high frequency value HF0′ instead of from the reference high frequency value HF0. To further illustrate, during the bin 1 of the cycle (n−m+p), the processor 114 controls the HF RF generator 104 to operate at the HF offset value HF(−3) from the reference high frequency value HF0′ in the same manner in which the processor 114 controls the HF RF generator 104 to operate at the HF offset value HF(−4) from the reference high frequency value HF0. The HF RF generator 104 is operated at the HF offset value HF(−3) during the bin 1 of the cycle (n−m+p). When the HF RF generator 104 operates at the HF offset value HF(−3), the processor 114 receives the voltage signal 212 during the bin 1 of the cycle (n−m+p), and determines a value of the parameter for the bin 1 of the cycle (n−m+p) in the same manner in which the first value of the parameter for the bin 1 of the cycle (n−m) is calculated. Similarly, the processor 114 controls the HF RF generator 104 to operate at different HF offset values during the bins 2 through 10 of the cycle (n−m+p) to determine remaining values of the parameter of the second set.

Continuing further with the example, the processor 114 then calculates a statistical value, such as an average or a median, of the second set of values of the parameter to output a second statistical parameter value. The processor 114 compares the first statistical parameter value with the second statistical parameter value to determine whether the first statistical parameter value is less than the second statistical parameter value. Upon determining that the first statistical parameter value is less than the second statistical parameter value, the processor 114 determines that the HF RF generator 104 is to be operated at the reference high frequency value HF0, and controls the HF RF generator 104 to operate at the reference high frequency value HF0 during the bin 0 of one or more of the cycles n, (n+1) and so on. On the other hand, upon determining that the second statistical parameter value is less than the first statistical parameter value, the processor 114 determines that the HF RF generator 104 is to be operated at the reference high frequency value HF0′, and controls the HF RF generator 104 to operate at the reference high frequency value HF0′ during the bin 0 of one or more of the cycles n, (n+1) and so on.

As another illustration, instead of using all of the bins, such as the 10 bins or 20 bins, to determine the first statistical parameter value or the second statistical parameter value in the preceding example, a pre-determined number of bins, such as less than all of the bins of each cycle (n−m) and (n−m+p), are used. To further illustrate, the processor 114 accesses, such as reads, voltages of the voltage signal 212 measured during the bins 4 through 7 of the cycles (n−m+p) and (n−m) from the memory device 114, and determines, from the voltages measured during the bins 4 through 7 of the cycle (n−m), the first statistical parameter value for the bins 4 through 7 of the cycle (n−m). In the further illustration, the processor 114 determines from the voltages measured during the bins 4 through 7 of the cycle (n−m+p), the second statistical parameter value for the bins 4 through 7 of the cycle (n−m+p). As another further illustration, the processor 114 determines the first statistical parameter value for the bins 3 through 7 of the cycle (n−m) instead of the bins 1 through 10 and the second statistical parameter value for the bins 3 through 7 of the cycle (n−m+p) instead of the bins 1 through 10.

The pre-determined number of bins includes the bin 0. As an instance, the pre-determined number of bins is received from a user via an input device, such as a mouse or a keyboard or a keypad, that is coupled to the processor 114. As another instance, an identification of the bins of the pre-determined number is received from the user via the input device. To further illustrate, the user selects that the bins 4 through 7 or the bins 1 through 6 or the bins 4 through 10 be used to determine the first statistical parameter value or the second statistical parameter value. As another instance, the pre-determined number includes all the bins, such as 10 or 20 bins, of each cycle (n−m) and (n−m+p).

As another example, the processor 114 controls the HF RF generator 102 to operate at the reference high frequency value HF0 during the bin 0 of the cycle (n−m). When the HF RF generator 102 is operated at the reference high frequency value HF0 to generate the RF signal 152 having the reference high frequency value HF0, the processor 114 determines a first VSWR value for the bin 0 of the cycle (n−m) as a ratio of a first sum and a second sum. The first sum is a total of 1 and a magnitude of the first statistical parameter value and the second sum is a difference between 1 and the magnitude of the first statistical parameter value. Moreover, the processor 114 controls the HF RF generator 102 to operate at the reference high frequency value HF0′ during the bin 0 of the cycle (n−m+p). When the HF RF generator 102 is operated at the reference high frequency value HF0′ to generate the RF signal 152 having the reference high frequency value HF0′, the processor 114 determines a second VSWR value for the bin 0 of the cycle (n−m+p) as a ratio of a third sum and a fourth sum. The third sum is a total of 1 and a magnitude of the second statistical parameter value and the fourth sum is a difference between 1 and the magnitude of the second statistical parameter value. The processor 114 then determines whether the first VSWR value is less than the first VSWR value. Upon determining that the first VSWR value is less than the second VSWR value, the processor 114 controls the HF RF generator 102 to operate at the reference high frequency value HF0. On the other hand, in response to determining that the second VSWR value is less than the first VSWR value, the processor 114 controls the HF RF generator 102 to operate at the reference high frequency value HF0′.

As another illustration, instead of using all of the bins, such as the 10 bins or 20 bins, to determine the first VSWR value or the second VSWR value in the preceding example, the pre-determined number of bins is used. For instance, less than all of the bins each cycle (n−m) and (n−m+p) are used. To further illustrate, the processor 114 accesses, such as reads, voltages of the voltage signal 212 measured during the bins 4 through 7 of the cycles (n−m+p) and (n−m) from the memory device 114, and determines, from the voltages measured during the bins 4 through 7 of the cycle (n−m), the first VSWR value for the bins 4 through 7 of the cycle (n−m). In the further illustration, the processor 114 determines from the voltages measured during the bins 4 through 7 of the cycle (n−m+p), the second VSWR for the bins 4 through 7 of the cycle (n−m+p). As another further illustration, the processor 114 determines the first VSWR for the bins 3 through 7 of the cycle (n−m) instead of the bins 1 through 10 and the second VSWR for the bins 3 through 7 of the cycle (n−m+p) instead of the bins 1 through 10.

The processor 114 controls the HF RF generator 102 to operate at a reference high frequency value during the bin 0 of any cycle of the clock signal 202 (FIG. 2A). For example, the processor 114, includes within the recipe signal 144 (FIG. 1), the reference high frequency value, such as HF0 or HF0′, for the bin 0. The processor 114 further includes, within the recipe signal 144, a time interval for the bin 0, and an association, such as a unique relationship or a link, between the high frequency value for the bin 0 and the time interval for the bin 0. The processor 114 sends the recipe signal 144 to the HF RF generator 104. Upon receiving the recipe signal 144, a controller within the HF RF generator 104 determines that the HF RF generator 104 is to generate the RF signal 152 having the reference high frequency value HF0 or HF0′ during the time interval for the bin 0. The controller of the HF RF generator 104 controls a power supply of the HF RF generator 104 to generate the RF signal 152 to having the reference high frequency value HF0 or HF0′ during the time interval of the bin 0.

Similarly, the processor 114 controls the HF RF generator 102 to operate at an HF offset value during a corresponding one of the remaining bins 1 through 4 and 6 through 10 of any cycle of the clock signal 202. For example, the processor 114, includes within the recipe signal 144 (FIG. 1), the HF offset value, such as HF(−4), for the bin 1. The processor 114 further includes, within the recipe signal 144, a time interval for the bin 1, and an association, such as a unique relationship or a link, between the HF offset value for the bin 1 and the time interval for the bin 1. The processor 114 sends the recipe signal 144 to the HF RF generator 104. Upon receiving the recipe signal 144, the controller within the HF RF generator 104 determines that the HF RF generator 104 is to generate the RF signal 152 having the HF offset value during the time interval for the bin 1. The controller of the HF RF generator 104 controls the power supply of the HF RF generator 104 to generate the RF signal 152 having the HF offset value HF(−4) during the time interval of the bin 1.

In one embodiment, the processor 114 applies dynamic frequency tuning (DFT) to determine the high frequency value HF0 that is stored in the memory device 116. For example, in DFT, the processor 114 determines the high frequency value HF0 by rotating a high frequency impedance trajectory on a Smith chart to minimize the parameter, such as the high frequency reflected power or gamma.

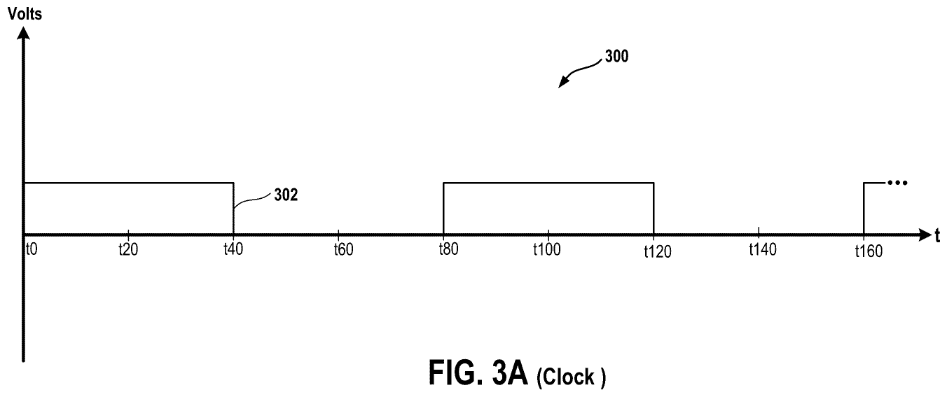

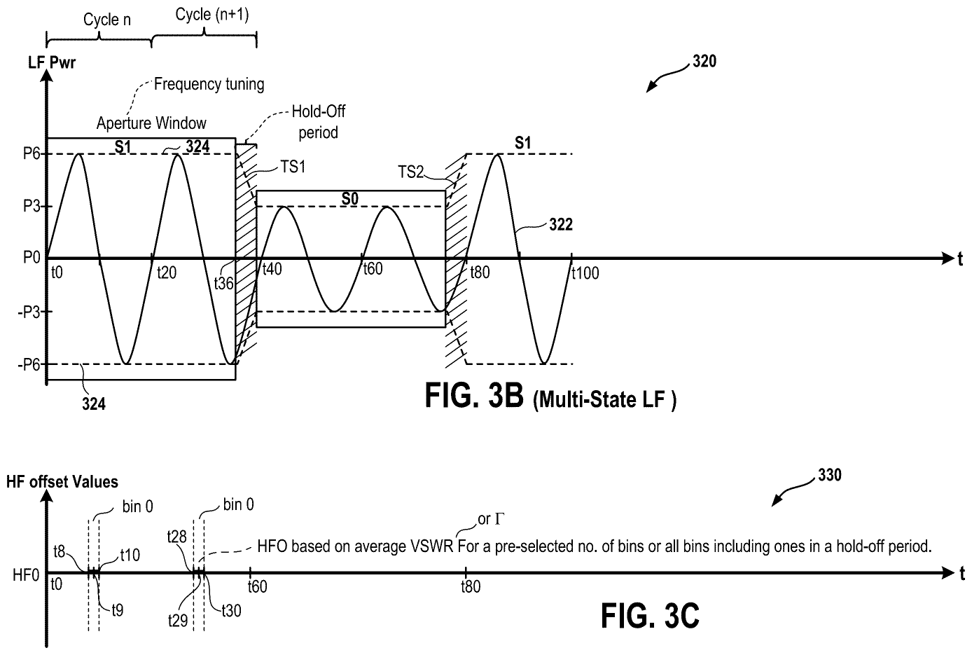

FIG. 3A is an embodiment of a graph 300 to illustrate a clock signal 302. The clock signal 302 different from the clock signal 202 (FIG. 2A), described above. An x-axis of the graph 300 plots the time t ranging from the time t0 to a time t160. A y-axis of the graph 300 plots a voltage of the clock signal 302. The clock signal 302 is generated by the processor 114 (FIG. 1).

The clock signal 302 transitions periodically between the logic level 1 and the logic level 0. The clock signal 302 transitions from the logic level 0 to the logic level 1 at the time t0 and remains at the logic level 1 from the time t0 to the time t40. At the time t40, the clock signal 302 transitions from the logic level 1 to the logic level 0, and remains at the logic level 0 from the time t40 to the time t80. The transitions between the logic levels 1 and 0 repeat from the time t80 to the time t160. The transitions between the logic levels 1 and 0 of the clock signal 302 are generated by the processor 114 and provided within the recipe signal 142 (FIG. 1) to the LF RF generator 102.

FIG. 3B is an embodiment of a graph 320 to illustrate power of an RF signal 322 that is generated by the LF RF generator 102 (FIG. 1). The RF signal 322 is an example of the RF signal 150 (FIG. 1) generated and supplied by the LF RF generator 102. The graph 320 plots an envelope 324 of power of the RF signal 322 versus the time t. The time t is plotted on an x-axis, which is the same as the x-axis of the graph 300 (FIG. 3A). The envelope 324 is plotted with reference to a y-axis of the graph 320. The y-axis plots power amounts ranging from −P6 to zero and from zero to P6. It should be noted that the power amounts increase from −P6 to P6. For example, the power amount −P5 is greater than the power amount −P6 and the power amount −P5 is greater than the power amount −P4 and so on.

The envelope 324 is of power of the RF signal 322. For example, the envelope 324 is a peak-to-peak amplitude of power of the RF signal 322. The envelope 324 transitions periodically, in synchronization with the clock signal 302, between a state S1 of the RF signal 322 and a state S0 of the RF signal 322. For example, the envelope 324 transitions from the power level P3 to the power level P6 and from the power level −P3 to the power level −P6 at the time t0 and remains at the power levels P6 and −P6 from the time t0 to the time t40. The power levels P6 and −P6 represent the state S1 of the RF signal 322. The envelope 324 transitions from the power level P6 to the power level P3 and from the power level −P6 to the power level −P3 during a time period from the time t36 to the time t40 to form a transition state TS1 of the RF signal 322. The envelope 324 remains at the power levels P3 and −P3 from the time t40 to the time t80 to form the state S0 of the RF signal 322. The envelope 324 transitions from the power level P3 to the power level P6 and from the power level −P3 to the power level −P6 during a time period from the time t76 to the time t80 to form a transition state TS2 of the RF signal 322. In this manner, the power levels P6 and −P6 and P3 and −P3 repeat from the time t80 to the time t160. Also, a power level of the RF signal 322 represents a state, such as the S1 or the state S0, of the RF signal 322. The transitions between the logic levels 1 and 0 of the clock signal 302 are generated by the processor 114 and provided within the recipe signal 142 (FIG. 1) to the LF RF generator 102 to facilitate the RF signal 322 to transition synchronously with the clock signal 302.

Steady states of the RF signal 322 occur during time periods in which the RF signal 322 does not transition from one state to another and the transition states of the RF signal 322 occur during timer periods in which the RF signal 322 transitions from one state to another. For example, a first steady state is the state S1 of the RF signal 322 and a second steady state is the state S0 of the RF signal 322. The state S1 occurs during a first time period from the time to to the time t36 and the state S0 occurs during a second time period from the time t40 to the time t76. Each of the first and second time periods is a tuning window. As an example, the first transition state TS1 is a state of the RF signal 322 during a time period from the time t36 to the time t40 and the second transition state TS2 is a state of the RF signal 322 during a time period from the time t76 to the time t80. In the first transition state, the RF signal 322 transitions from the state S1 to the state S0 and in the second transition state, the RF signal 322 transitions from the state S0 to the state S1. As an example, during a transition state, power values of the RF signal 322 change more frequently compared to change in power values of RF signal 322 during a steady state. Also, as another example, during a transition state, a positive slope or a negative slope due to a change in a power level of a state of the RF signal 322 is created. During a steady state, a slope of a power level is substantially zero or zero.

In one embodiment, instead of the RF signal 322, another RF signal generated by the HF RF generator 104 (FIG. 1) is used. The other RF signal is an example of the RF signal 152 (FIG. 1) generated by the HF RF generator 104. The other RF signal transitions from a state S1 to a state S0 and from the state S0 to the state S1 synchronous with the clock signal 302 in the same manner in which the RF signal 322 transitions between the states S1 and S0. During the state S1, the other RF signal has a greater power level compared to a power level of the other RF signal during the state S0. The transitions between the logic levels 1 and 0 of the clock signal 302 are generated by the processor 114 and provided within the recipe signal 144 (FIG. 1) to the HF RF generator 104 to facilitate the other RF signal to transition synchronously with the clock signal 302.

In an embodiment, both the RF signals 150 and 152 transition periodically between their corresponding states S1 and S0 synchronous with the clock signal 302.

FIG. 3C is an embodiment of a graph 330 to illustrate that values of the parameter during a hold-off period at which a transition state occurs are used to determine the reference high frequency value HF0. The hold-off period is illustrated by oblique lines in the graph 320 (FIG. 3B). The hold-off period is one during which any of the transition states TS1 or TS2 (FIG. 3B) occur. The graph 330 plots the HF offset values of the HF RF generator 104 versus the time t. The HF offset values of the HF RF generator 104 are plotted on a y-axis, which is the same as the y-axis of the graph 300 (FIG. 3A). The time t is plotted on an x-axis, which is the same as the x-axis of the graph 300. It should be noted that at the time t29 of the cycle (n+1), another negative zero crossing of the voltage signal 212 (FIG. 2B) occurs.

The processor 114 (FIG. 1) determines the reference high frequency value HF0 to be applied during the cycles n, (n+1) and so on based on values of the parameter calculated for the transition states of the RF signal 322 that occur during the pre-determined number of bins of the cycles (n−m) and (n−m+p). For example, the processor 114 determines the reference high frequency value HF0 for a pre-determined time interval, such as the bin 0 of the cycles n, (n+1), and so on of the clock signal 202 (FIG. 2A), in the same manner as that described above with reference to FIG. 2C and in addition, the processor 114 takes into account the values of the parameter calculated for the transition states, of the RF signal 322, occurring during the pre-determined number of bins of the cycles (n−m) and (n−m+p).

As another example, to determine the reference high frequency value HF0 to be applied during the cycles n, (n+1) and so on, the processor 114 does not ignore parameter values that are calculated based on the voltage signal 212 (FIG. 2B) received by the processor 114 from the V sensor 110 during the occurrence of the transition state, such as TS2, within the cycle (n−m). In the example, the transition state TS2 precedes the steady state S1 of the cycle (n−m). To illustrate, the processor 114 controls the HF RF generator 104 to operate at the reference high frequency value HF0 during the bin 0 of the cycle (n−m) of the clock signal 202. Also, in the illustration, the processor 114 controls the HF RF generator 104 to operate at the HF offset values of the RF signal 152 during the bins of the cycle (n−m) in which the transition state TS2 of the cycle (n−m) occurs. In the illustration, the processor 114 controls the HF RF generator 104 to operate at the HF offset values and at the reference high frequency value HF0 during the bins in which the steady state of the cycle (n−m) that immediately follows the transition state TS2 of the cycle (n−m) occurs. In the illustration, a number of the bins of the cycle (n−m) during which the transition state TS2 and the steady state S1 that immediately follows the transition state TS2 occur is equal to the pre-determined number of bins. In the illustration, a correspondence between each of the HF offset values or the reference high frequency value HF0 and a respective time interval, such as a respective bin, for which each of the HF offset values or the reference high frequency value HF0 is to be applied by the processor 114 is stored in the memory device 116, and accessed from the memory device 116 by the processor 114. Further, in the illustration, the HF offset value or the reference high frequency value HF0 is accessed for controlling the HF RF generator 104 to operate at the HF offset value or the reference high frequency value HF0.

Continuing with the illustration, one or more values of the voltage signal 212 are received from the V sensor 110 during the pre-determined number of bins for which the transition state TS2 and the steady state S1 of the cycle (n−m) occur. In the illustration, during the time period of the pre-determined number of bins, the HF RF generator 104 is operated at the reference high frequency value HF0 and the HF offset values. In the illustration, the processor 114 determines, based on the one or more values of the voltage signal 212 during the pre-determined number of bins for which the transition state TS2 and the steady state S1 that immediately follows the transition state TS2 occur, a value of the parameter for each bin of the cycle (n−m). The value of the parameter is determined for any bin of the cycle (n−m) during occurrence of the transition state TS2 from the one or more values of the voltage signal 212 in the same manner as that described above with reference to FIG. 2C in which the processor 114 determines the first value of the parameter for the bin 1 of the cycle (n−m). In this manner, multiple values of the parameter for the transition state TS2 of the cycle (n−m) are determined by the processor 114. The processor 114 determines a statistical value of the parameter from the values of the parameter for the pre-determined number of bins for the transition state TS2 of the cycle (n−m) and the immediately following steady state S1 of the cycle (n−m) in the same manner in which the processor 114 determines the first statistical parameter value from the first set or the primary statistical value from the primary set. The processor 114 compares the statistical value with another statistical value, such as the second statistical parameter value or the secondary statistical value, of the parameter to determine whether the statistical value is less than the other statistical value. The other statistical value is determined in the same manner in which the statistical value is determined except the other statistical value is determined for the pre-determined number of bins of the cycle (n−m+p) and when the reference high frequency value HF0′ is applied to the HF RF generator 104. It should be noted that also during the cycle (n−m+p), the transition state TS2 and the steady state S1 occur during the pre-determined number of bins of the cycle (n−m+p).

Based on the comparison, the processor 114 determines to control the HF RF generator 104 to operate at the reference high frequency value HF0 and controls the HF RF generator 104 to operate at the reference high frequency value HF0 during the pre-determined time interval, such as the bin 0, of the cycles n, (n+1), and so on. For example, when the statistical value is less than the other statistical value, the processor 114 determines to control the HF RF generator 104 to operate at the reference high frequency value HF0. On the other hand, when the other statistical value is less than the statistical value, the processor 114 determines to control the HF RF generator 104 to operate at the reference high frequency value HF0′.

In one embodiment, the statistical value determined in the preceding illustration is instead based on the parameter values calculated for the transition state TS1 and the steady state S0 that immediately follows the transition state TS1 during the cycle (n−m). Also, the other statistical value determined in the preceding illustration is instead based on the parameter values calculated for the transition state TS1 and the steady state S0 that immediately follows the transition state TS1 during the cycle (n−m+p).

Embodiments, described herein, may be practiced with various computer system configurations including hand-held hardware units, microprocessor systems, microprocessor-based or programmable consumer electronics, minicomputers, mainframe computers and the like. The embodiments, described herein, can also be practiced in distributed computing environments where tasks are performed by remote processing hardware units that are linked through a computer network.

In some embodiments, a controller is part of a system, which may be part of the above-described examples. The system includes semiconductor processing equipment, including a processing tool or tools, chamber or chambers, a platform or platforms for processing, and/or specific processing components (a wafer pedestal, a gas flow system, etc.). The system is integrated with electronics for controlling its operation before, during, and after processing of a semiconductor wafer or substrate. The electronics is referred to as the “controller,” which may control various components or subparts of the system. The controller, depending on processing requirements and/or a type of the system, is programmed to control any process disclosed herein, including a delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks connected to or interfaced with the system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, one or more microprocessors, or microcontrollers that execute program instructions (e.g., software). The program instructions are instructions communicated to the controller in the form of various individual settings (or program files), defining operational parameters for carrying out a process on or for a semiconductor wafer. The operational parameters are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer system, which allows for remote access for wafer processing. The controller enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to the system over a computer network, which includes a local network or the Internet. The remote computer includes a user interface that enables entry or programming of parameters and/or settings, which are then communicated to the system from the remote computer. In some examples, the controller receives instructions in the form of settings for processing a wafer. It should be understood that the settings are specific to a type of process to be performed on a wafer and a type of tool that the controller interfaces with or controls. Thus as described above, the controller is distributed, such as by including one or more discrete controllers that are networked together and working towards a common purpose, such as the fulfilling processes described herein. An example of a distributed controller for such purposes includes one or more integrated circuits on a chamber in communication with one or more integrated circuits located remotely (such as at a platform level or as part of a remote computer) that combine to control a process in a chamber.

Without limitation, in various embodiments, a plasma system, described herein, includes a plasma etch chamber, a deposition chamber, a spin-rinse chamber, a metal plating chamber, a clean chamber, a bevel edge etch chamber, a physical vapor deposition (PVD) chamber, a chemical vapor deposition (CVD) chamber, an atomic layer deposition (ALD) chamber, an atomic layer etch (ALE) chamber, an ion implantation chamber, a track chamber, or any other semiconductor processing chamber that is associated or used in fabrication and/or manufacturing of semiconductor wafers.

It is further noted that although the above-described operations are described with reference to a parallel plate plasma chamber, e.g., a capacitively coupled plasma chamber, etc., in some embodiments, the above-described operations apply to other types of plasma chambers, e.g., a plasma chamber including an inductively coupled plasma (ICP) reactor, a transformer coupled plasma (TCP) reactor, conductor tools, dielectric tools, a plasma chamber including an electron cyclotron resonance (ECR) reactor, etc. For example, an X MHz RF generator, a Y MHz RF generator, and a Z MHz RF generator are coupled to an inductor within the ICP plasma chamber.

As noted above, depending on a process operation to be performed by the tool, the controller communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These computer-implemented operations are those that manipulate physical quantities.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations, described herein, are performed by a computer selectively activated, or are configured by one or more computer programs stored in a computer memory, or are obtained over a computer network. When data is obtained over the computer network, the data may be processed by other computers on the computer network, e.g., a cloud of computing resources.

One or more embodiments, described herein, can also be fabricated as computer-readable code on a non-transitory computer-readable medium. The non-transitory computer-readable medium is any data storage hardware unit, e.g., a memory device, etc., that stores data, which is thereafter read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although some method operations, described above, were presented in a specific order, it should be understood that in various embodiments, other housekeeping operations are performed in between the method operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment described above are combined with one or more features of any other embodiment without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein, but may be modified within the scope and equivalents of the appended claims.

1. A method for reducing radio frequency (RF) power reflected towards a high frequency (HF) RF generator in a bin independent manner, comprising:
receiving a voltage signal from an output of a match coupled to a low frequency (LF) RF generator and the HF RF generator;
dividing the voltage signal into a plurality of bins for each cycle of an LF RF signal generated by the LF RF generator;
identifying a first bin from the plurality of bins during which a zero crossing occurs;
accessing measurements of a parameter for occurrences of a pre-determined number of the plurality of bins;
calculating a frequency of operation of the HF RF generator for the first bin based on the measurements of the parameter;
controlling the HF RF generator to operate at the frequency of operation during an occurrence of the first bin.

2. The method of claim 1, wherein said calculating the frequency of operation of the HF RF generator based on the measurements of the parameter includes:
determining a first value of the frequency of operation of the HF RF generator for which a first statistical value is determined from a first plurality of the measurements;
determining a second value of the frequency of operation of the HF RF generator for which a second statistical value is determined from a second plurality of the measurements;
determining that the first value is less than the second value;
determining the first value to be the frequency of operation of the HF RF generator during the occurrence of the first bin.

3. The method of claim 1, wherein the measurements include values received during a transition state associated with power of the LF RF signal generated by the LF RF generator.

4. The method of claim 1, wherein the parameter is a reflection coefficient or voltage standing wave ratio.

5. The method of claim 1, wherein the voltage signal has a negative slope at the zero crossing.

6. The method of claim 1, wherein the pre-determined number includes all of the plurality of bins for each cycle.

7. The method of claim 1, wherein the pre-determined number includes less than all of the plurality of bins for each cycle.

8. A controller for reducing radio frequency (RF) power reflected towards a high frequency (HF) RF generator in a bin independent manner, comprising:
a processor configured to:
receive a voltage signal from an output of a match coupled to a low frequency (LF) RF generator and the HF RF generator;
divide the voltage signal into a plurality of bins for each cycle of an LF RF signal generated by the LF RF generator;
identify a first bin from the plurality of bins during which a zero crossing occurs;
access measurements of a parameter for occurrences of a pre-determined number of the plurality of bins;
calculate a frequency of operation of the HF RF generator for the first bin based on the measurements of the parameter;
control the HF RF generator to operate at the frequency of operation during an occurrence of the first bin; and
a memory device coupled to the processor.

9. The controller of claim 8, wherein to calculate the frequency of operation of the HF RF generator based on the measurements of the parameter, the processor is configured to:
determine a first value of the frequency of operation of the HF RF generator for which a first statistical value is determined from a first plurality of the measurements;
determine a second value of the frequency of operation of the HF RF generator for which a second statistical value is determined from a second plurality of the measurements;
determine that the first value is less than the second value;
determine the first value to be the frequency of operation of the HF RF generator during the occurrence of the first bin.

10. The controller of claim 8, wherein the measurements include values received during a transition state associated with power of the LF RF signal generated by the LF RF generator.

11. The controller of claim 8, wherein the parameter is a reflection coefficient or a voltage standing wave ratio.

12. The controller of claim 8, wherein the voltage signal has a negative slope at the zero crossing.

13. The controller of claim 8, wherein the pre-determined number includes all of the plurality of bins for each cycle.

14. The controller of claim 8, wherein the pre-determined number includes less than all of the plurality of bins for each cycle.

15. A plasma system comprising:
a low frequency (LF) RF generator configured to generate an LF RF signal;
a high frequency (HF) RF generator configured to generate an HF RF signal;
a match coupled to the LF RF generator and the HF RF generator, wherein the match is configured to receive the LF RF and HF RF signals to output a modified RF signal; and
a controller coupled to the LF RF generator, the HF RF generator, and the match, wherein the controller is configured to:
receive a voltage signal from an output of the match;
divide the voltage signal into a plurality of bins for each cycle of the LF RF signal;
identify a first bin from the plurality of bins during which a zero crossing occurs;
access measurements of a parameter for occurrences of a pre-determined number of the plurality of bins;
calculate a frequency of operation of the HF RF generator for the first bin based on the measurements of the parameter;
control the HF RF generator to operate at the frequency of operation during an occurrence of the first bin.

16. The plasma system of claim 15, wherein to calculate the frequency of operation of the HF RF generator based on the measurements of the parameter, the controller is configured to:
determine a first value of the frequency of operation of the HF RF generator for which a first statistical value is determined from a first plurality of the measurements;
determine a second value of the frequency of operation of the HF RF generator for which a second statistical value is determined from a second plurality of the measurements;
determine that the first value is less than the second value;
determine the first value to be the frequency of operation of the HF RF generator during the occurrence of the first bin.

17. The plasma system of claim 15, wherein the measurements include values received during a transition state associated with power of the LF RF signal generated by the LF RF generator.

18. The plasma system of claim 15, wherein the parameter is a reflection coefficient or a voltage standing wave ratio.

19. The plasma system of claim 15, wherein the voltage signal has a negative slope at the zero crossing.

20. The plasma system of claim 15, wherein the pre-determined number includes less than all of the plurality of bins for each cycle.
